(19) United States
(12) Patent Application Publication
(10) Pub. No.: US 2026/0156833 A1
(43) Pub. Date: Jun. 4, 2026

(54) MAGNETIZATION ROTATIONAL ELEMENT, MAGNETORESISTANCE EFFECT ELEMENT, AND MAGNETIC MEMORY

(71) Applicant: TDK CORPORATION, Tokyo (JP)

(72) Inventors: Tomoyuki SASAKI, Tokyo (JP); Yohei SHIOKAWA, Tokyo (JP)

(73) Assignee: TDK CORPORATION, Tokyo (JP)

(21) Appl. No.: 18/705,196

(22) PCT Filed: Dec. 13, 2021
(86) PCT No.: PCT/JP2021/045829

§ 371 Date: Apr. 26, 2024

(51) Int. Cl. H10B 61/00; H10N 50/01; H10N 50/10

(52) U.S. Cl. CPC H10B 61/20; H10N 50/01; H10N 50/10

(57) ABSTRACT

This magnetization rotational element includes a spin-orbit torque wiring, and a first ferromagnetic layer connected to the spin-orbit torque wiring, in which the spin-orbit torque wiring has a length in a first direction larger than a length in a second direction when viewed from a lamination direction, and the spin-orbit torque wiring has different constituent elements between a first region and a second region having a symmetrical positional relationship with respect to a reference plane which passes through a geometric center of the first ferromagnetic layer when viewed from the lamination direction and is orthogonal to the first direction, and is asymmetrical in the first direction.

### TECHNICAL FIELD

The present invention relates to a magnetization rotational element, a magnetoresistance effect element, and a magnetic memory.

### BACKGROUND ART

A giant magnetoresistance (GMR) element formed of a multilayer film including a ferromagnetic layer and a non-magnetic layer, and a tunnel magnetoresistance (TMR) element in which an insulating layer (a tunnel barrier layer, a barrier layer) is used as a nonmagnetic layer are known as a magnetoresistance effect element. Magnetoresistance effect elements can be applied to magnetic sensors, high frequency components, magnetic heads, and magnetic random-access memories (MRAM).

An MRAM is a storage element in which magnetoresistance effect elements are integrated. In an MRAM, data is read and written by utilizing characteristics in which a resistance of a magnetoresistance effect element changes when directions of magnetization of two ferromagnetic layers sandwiching a nonmagnetic layer in the magnetoresistance effect element change. A magnetization direction of the ferromagnetic layer is controlled by utilizing, for example, a magnetic field generated by a current. Also, for example, the magnetization direction of the ferromagnetic layer is controlled by utilizing a spin transfer torque (STT) generated when a current is caused to flow in a lamination direction of the magnetoresistance effect element.

When a magnetization direction of the ferromagnetic layer is rewritten by utilizing the STT, a current is caused to flow in a lamination direction of the magnetoresistance effect element. A write current causes deterioration in characteristics of the magnetoresistance effect element.

In recent years, attention has been focused on a method that does not require a current to be caused to flow in a lamination direction of the magnetoresistance effect element during writing (for example, Patent Document 1). One of the methods is a write method utilizing a spin-orbit torque (SOT). The SOT is induced by a spin current generated by a spin-orbit interaction or by the Rashba effect at an interface between different materials. A current for inducing the SOT in a magnetoresistance effect element flows in a direction intersecting a lamination direction of the magnetoresistance effect element. That is, there is no need to cause a current to flow in a lamination direction of the magnetoresistance effect element, and thus a prolonged life of the magnetoresistance effect element is expected.

### CITATION LIST

### Patent Document

[Patent Document 1]
Japanese Unexamined Patent Application, First Publication No. 2017-216286

### SUMMARY OF INVENTION

### Technical Problem

It is said that a magnetoresistance effect element using an SOT needs to break a symmetry of magnetization reversal to achieve stable magnetization reversal. The symmetry of magnetization reversal can be broken by, for example, applying an external magnetic field. On the other hand, it is difficult to apply an appropriate external magnetic field to each of microscale elements. Also, providing a separate source for an external magnetic field will cause an element size to increase and a manufacturing process to become complicated. Therefore, there is a demand for a magnetization rotational element, a magnetoresistance effect element, and a magnetic memory in which stable magnetization reversal is possible even in an absence of a magnetic field.

The present invention has been made in view of the above circumstances, and an objective of the present invention is to provide a magnetization rotational element, a magnetoresistance effect element, and a magnetic memory in which stable magnetization reversal is possible even in an absence of a magnetic field.

### Solution to Problem

In order to solve the above-described problems, the present invention provides the following means.

A magnetization rotational element according to the present embodiment includes a spin-orbit torque wiring and a first ferromagnetic layer connected to the spin-orbit torque wiring. The spin-orbit torque wiring has a length in a first direction larger than a length in a second direction when viewed from a lamination direction. The spin-orbit torque wiring has a first region and a second region at different positions in the first direction. The first region and the second region are at positions symmetrical in the first direction with respect to a reference plane which passes through a geometric center of the first ferromagnetic layer when viewed from the lamination direction and is orthogonal to the first direction. The first region and the second region have different constituent elements.

### Advantageous Effects of Invention

The magnetization rotational element, the magnetoresistance effect element, and the magnetic memory according to the present invention are capable of magnetization reversal even in an absence of a magnetic field.

### BRIEF DESCRIPTION OF DRAWINGS

FIG. 1 is a circuit diagram of a magnetic memory according to a first embodiment.

FIG. 2 is a cross-sectional view of a characteristic portion of the magnetic memory according to the first embodiment.

FIG. 3 is a cross-sectional view of a magnetoresistance effect element according to the first embodiment.

FIG. 4 is a plan view of the magnetoresistance effect element according to the first embodiment.

FIG. 5 is a view for explaining a manufacturing method of the magnetoresistance effect element according to the first embodiment.

FIG. 6 is a view for explaining a manufacturing method of the magnetoresistance effect element according to the first embodiment.

FIG. 7 is a view for explaining a manufacturing method of the magnetoresistance effect element according to the first embodiment.

FIG. 8 is a view for explaining a manufacturing method of the magnetoresistance effect element according to the first embodiment.

FIG. 9 is a view for explaining a manufacturing method of the magnetoresistance effect element according to the first embodiment.

FIG. 10 is a cross-sectional view of a magnetoresistance effect element according to a second embodiment.

FIG. 11 is a cross-sectional view of a magnetoresistance effect element according to a third embodiment.

FIG. 12 is a view for explaining a manufacturing method of the magnetoresistance effect element according to the third embodiment.

FIG. 13 is a view for explaining a manufacturing method of the magnetoresistance effect element according to the third embodiment.

FIG. 14 is a cross-sectional view of a magnetoresistance effect element according to a fourth embodiment.

FIG. 15 is a cross-sectional view of a magnetoresistance effect element according to a fifth embodiment.

FIG. 16 is a cross-sectional view of a magnetization rotational element according to a sixth embodiment.

FIG. 17 is a cross-sectional view of a magnetoresistance effect element according to a seventh embodiment.

### DESCRIPTION OF EMBODIMENTS

Hereinafter, the present embodiment will be described in detail with reference to the drawings as appropriate. In the drawings used in the following description, there are cases in which characteristic portions are appropriately enlarged for convenience of illustration so that characteristics of the present invention can be easily understood, and dimensional proportions or the like of respective constituent elements may be different from actual ones. Materials, dimensions, and the like illustrated in the following description are merely examples, and the present invention is not limited thereto and can be implemented with appropriate modifications within a range in which the effects of the present invention are achieved.

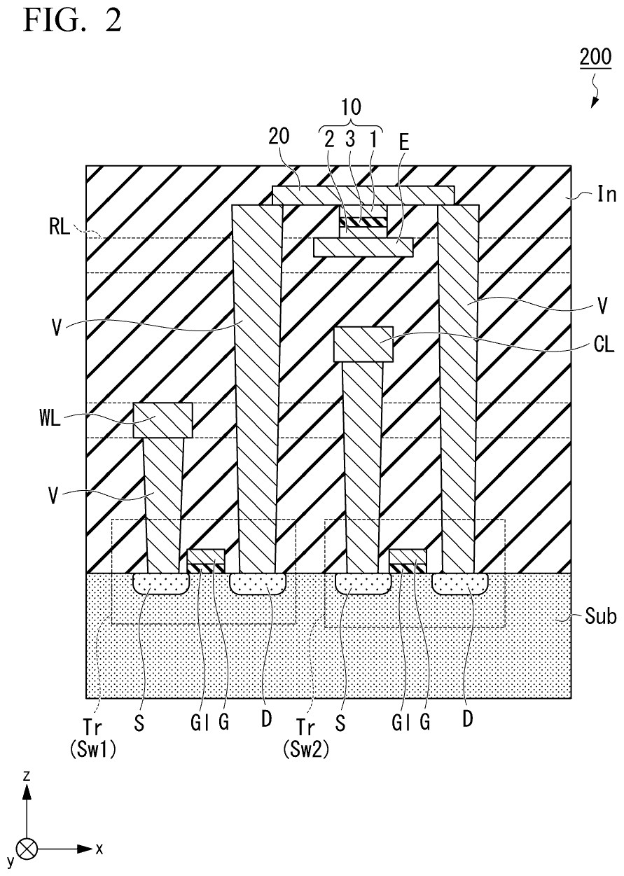

First, directions will be defined. One direction of one surface of a substrate Sub (see FIG. 2) to be described later is defined as an x direction, and a direction orthogonal to the x direction is defined as a y direction. The x direction is, for example, a longitudinal direction of a spin-orbit torque wiring 20. A z direction is a direction orthogonal to the x direction and the y direction. The z direction is an example of a lamination direction in which each layer is laminated. Hereinafter, a +z direction may be expressed as “upward” and a −z direction may be expressed as “downward”. The “upward” and the “downward” may not necessarily coincide with a direction in which gravity is applied.

In this specification, “extending in the x direction” means that, for example, a dimension in the x direction is larger than a minimum dimension of dimensions in the x direction, the y direction, and the z direction. The same applies to cases of extending in other directions. Also, the term “connection” in the present specification is not limited to a case of being physically connected. For example, not only a case in which two layers are physically in contact with each other, but also a case in which two layers are connected with another layer sandwiched therebetween are included in the “connection”. The “connection” in the present specification also includes an electrical connection.

### First Embodiment

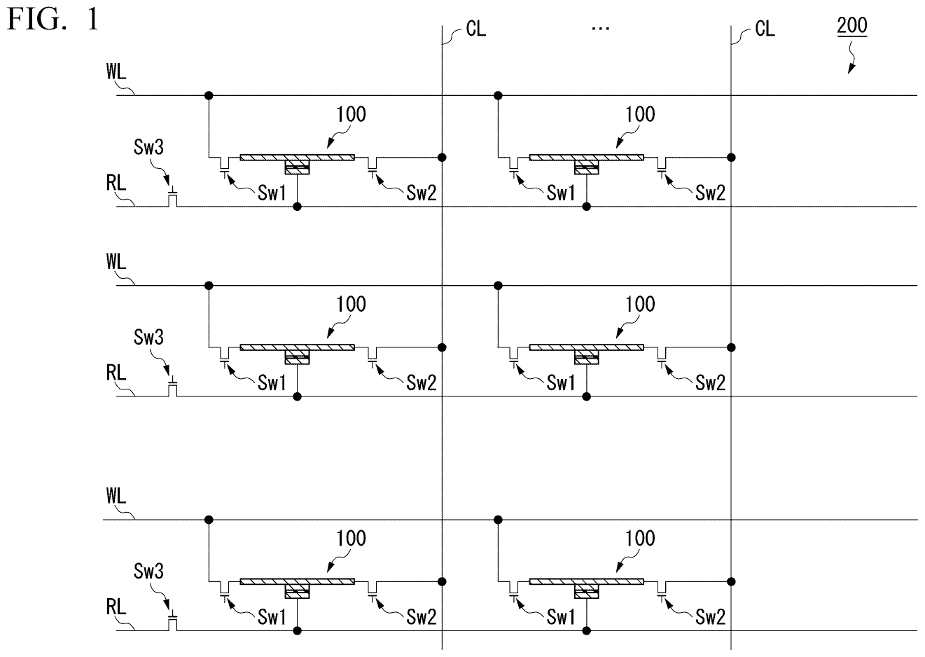

FIG. 1 is a configuration diagram of a magnetic memory 200 according to a first embodiment. The magnetic memory 200 includes a plurality of magnetoresistance effect elements 100, a plurality of write lines WL, a plurality of common lines CL, a plurality of read lines RL, a plurality of first switching elements Sw1, a plurality of second switching elements Sw2, and a plurality of third switching elements Sw3. In the magnetic memory 200, for example, the magnetoresistance effect elements 100 are disposed in an array.

Each of the write lines WL electrically connects a power supply and one or more magnetoresistance effect elements 100. Each of the common lines CL is a wiring used at both the time of writing and reading data. The common line CL electrically connects a reference potential and one or more magnetoresistance effect elements 100. The reference potential is, for example, the ground. The common line CL may be provided in each of the plurality of magnetoresistance effect elements 100, or may be provided across the plurality of magnetoresistance effect elements 100. Each of the read lines RL electrically connects the power supply and one or more magnetoresistance effect elements 100. The power supply is connected to the magnetic memory 200 at the time of use.

Each magnetoresistance effect element 100 is connected to the first switching element Sw1, the second switching element Sw2, and the third switching element Sw3. The first switching element Sw1 is connected between the magnetoresistance effect element 100 and the write line WL. The second switching element Sw2 is connected between the magnetoresistance effect element 100 and the common line CL. The third switching element Sw3 is connected to the read line RL extending over the plurality of magnetoresistance effect elements 100.

When a predetermined first switching element Sw1 and second switching element Sw2 are turned on, a write current flows between the write line WL and the common line CL which are connected to the predetermined magnetoresistance effect element 100. Due to the flow of the write current, data is written to the predetermined magnetoresistance effect element 100. When a predetermined second switching element Sw2 and third switching element Sw3 are turned on, a read current flows between the common line CL and the read line RL which are connected to the predetermined magnetoresistance effect element 100. Due to the flow of the read current, data is read from the predetermined magnetoresistance effect element 100.

The first switching element Sw1, the second switching element Sw2, and the third switching element Sw3 are elements that control a flow of a current. The first switching element Sw1, the second switching element Sw2, and the third switching element Sw3 are, for example, transistors, elements utilizing a change in phase of a crystal layer such as ovonic threshold switches (OTS), elements utilizing a change in band structure such as metal-insulator transition (MIT) switches, elements utilizing a breakdown voltage such as Zener diodes and avalanche diodes, or elements whose conductivities change as an atomic position changes.

In the magnetic memory 200 illustrated in FIG. 1, the magnetoresistance effect elements 100 connected to the same read line RL share the third switching element Sw3. The third switching element Sw3 may be provided in each of the magnetoresistance effect elements 100. Also, the third switching element Sw3 may be provided in each of the magnetoresistance effect elements 100, and shared by the magnetoresistance effect element 100 in which the first switching element Sw1 or the second switching element Sw2 is connected to the same wiring.

FIG. 2 is a cross-sectional view of a characteristic portion of the magnetic memory 200 according to the first embodiment. FIG. 2 is a cross section of the magnetoresistance effect element 100 taken along an xz plane passing through a center of a width in the y direction of a spin-orbit torque wiring 20 to be described later.

The first switching element Sw1 and the second switching element Sw2 illustrated in FIG. 2 are transistors Tr. The third switching element Sw3 is electrically connected to the read line RL, and is positioned, for example, at a different position in the x direction in FIG. 2. The transistor Tr is, for example, a field effect transistor, and includes a gate electrode G, a gate insulating film GI, and a source S and a drain D formed in the substrate Sub. The source S and drain D are defined by a direction of a current flow and are in the same region. A positional relationship between the source S and the drain D may be reversed. The substrate Sub is, for example, a semiconductor substrate.

The transistor Tr and the magnetoresistance effect element 100 are electrically connected through a via wiring V. The via wiring V is connected to, for example, an upper or lower surface of the spin-orbit torque wiring 20 of the magnetoresistance effect element 100. Also, the transistor Tr is connected to the write line WL or the common line CL by the via wiring V. The via wiring V extends, for example, in the z direction. The read line RL is connected to a laminate 10 via an electrode E. The via wiring V and the electrode E contain a material having conductivity.

A vicinity of the magnetoresistance effect element 100 and the transistor Tr is covered with an insulating layer In. The insulating layer In is an insulating layer that insulates between wirings of multilayer wirings and between elements. The insulating layer In may be formed of, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

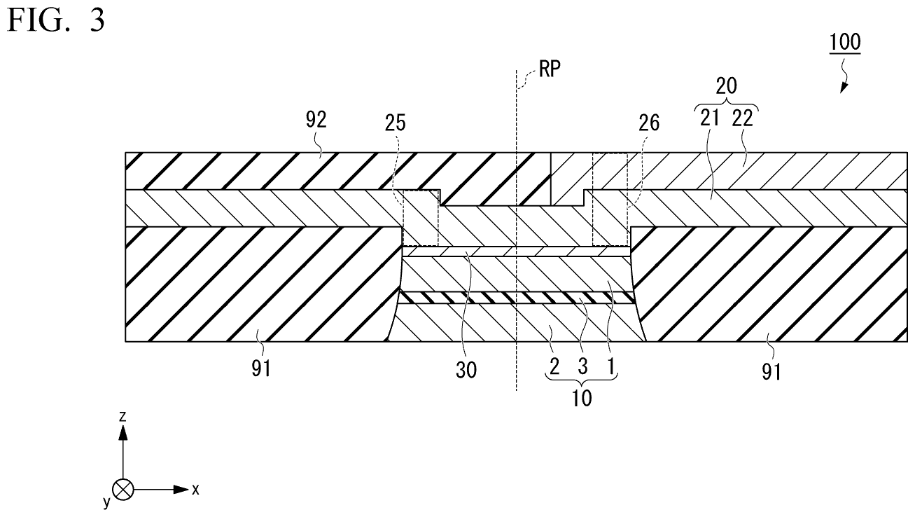

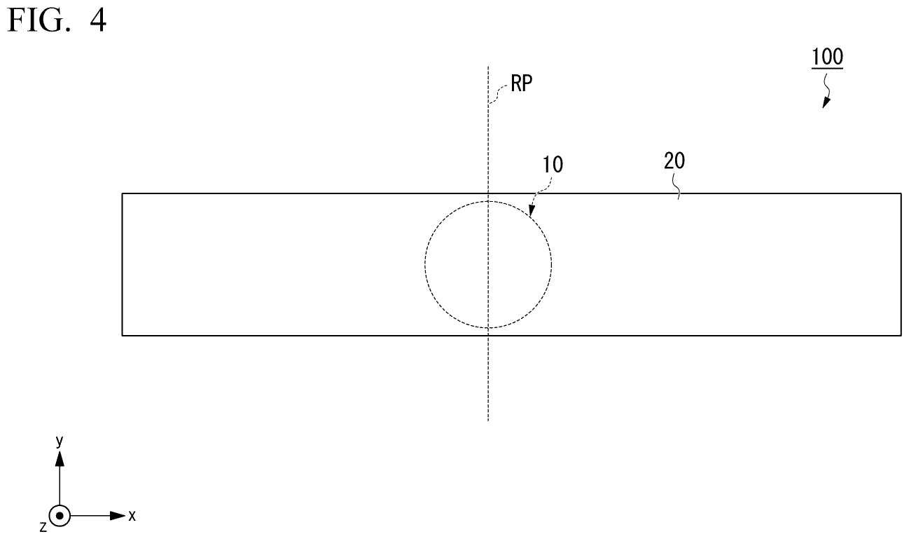

FIG. 3 is a cross-sectional view of the magnetoresistance effect element 100. FIG. 3 is a cross section of the magnetoresistance effect element 100 taken along the xz plane passing through a center of a width of the spin-orbit torque wiring 20 in the y direction. FIG. 4 is a plan view of the magnetoresistance effect element 100 from the z direction.

The magnetoresistance effect element 100 includes, for example, the laminate 10, the spin-orbit torque wiring 20, and a cap layer 30. The laminate 10 has a first ferromagnetic layer 1, a second ferromagnetic layer 2, and a nonmagnetic layer 3. A vicinity of the magnetoresistance effect element 100 is covered with, for example, a first insulating layer 91 and a second insulating layer 92. The first insulating layer 91 and the second insulating layer 92 are part of the insulating layer In described above.

The first insulating layer 91 is on the same layer as the laminate 10. The first insulating layer 91 surrounds a circumference of the laminate 10 in a plan view from the z direction. The second insulating layer 92 is on the same layer as the spin-orbit torque wiring 20. The second insulating layer 92 surrounds a circumference of the spin-orbit torque wiring 20, for example, in a plan view from the z direction.

The magnetoresistance effect element 100 is a magnetic element utilizing a spin-orbit torque (SOT), and may be referred to as a spin-orbit torque magnetoresistance effect element, a spin-injection magnetoresistance effect element, or a spin-current magnetoresistance effect element.

The magnetoresistance effect element 100 is an element that records and stores data. The magnetoresistance effect element 100 records data using a resistance value of the laminate 10 in the z direction. The resistance value of the laminate 10 in the z direction changes when a write current is applied along the spin-orbit torque wiring 20 and spins are injected from the spin-orbit torque wiring 20 into the laminate 10. The resistance value of the laminate 10 in the z direction can be read when a read current is applied in the z direction of the laminate 10.

The spin-orbit torque wiring 20 has, for example, a length in the x direction larger than that in the y direction when viewed from the z direction, and extends in the x direction. The write current flows in the x direction along the spin-orbit torque wiring 20.

The spin-orbit torque wiring 20 generates a spin current due to a spin Hall effect when a current flows therethrough, and injects spins into the first ferromagnetic layer 1. For example, the spin-orbit torque wiring 20 applies magnetization of the first ferromagnetic layer 1 with a spin-orbit torque (SOT) in an amount, for example, that can reverse the magnetization of the first ferromagnetic layer 1.

The spin Hall effect is a phenomenon in which a spin current is induced in a direction orthogonal to a direction in which a current flows on the basis of a spin-orbit interaction when the current is caused to flow. The spin Hall effect is the same as a normal Hall effect in that a movement (traveling) direction of moving (traveling) charge (electron) is bent. In the normal Hall effect, a movement direction of charged particles moving in a magnetic field is bent by a Lorentz force. On the other hand, in the spin Hall effect, a movement direction of spin is bent due to only movement of electrons (due to only a flow of current) even though a magnetic field is absent.

For example, when a current flows in a wiring in the x direction, a spin current is generated in both the x direction and z direction. Due to the spin current, spins (for example, +spins) polarized in the +y direction are unevenly distributed on a first surface of the wiring, and spins (for example, −spins) polarized in a direction opposite to the −y direction are unevenly distributed on a second surface facing the first surface. The spins accumulated on the first surface or second surface are injected into an adjacent layer.

The spin-orbit torque wiring 20 has a first region 25 and a second region 26. Both the first region 25 and the second region 26 are regions surrounding a predetermined range in the spin-orbit torque wiring 20.

The first region 25 and the second region 26 are at positions symmetrical in the x direction with respect to the reference plane RP. The reference plane RP is a plane that passes through a geometric center of the first ferromagnetic layer 1 when viewed from the z direction and is orthogonal to the x direction. A distance between the first region 25 and the reference plane RP is equal to a distance between the second region 26 and the reference plane RP. The first region 25 and the second region 26 have different constituent elements. The constituent elements of the first region 25 and the second region 26 are asymmetric in the x direction with respect to the reference plane RP. Here, the constituent element refers to, for example, a composition, a material, a layer configuration, a size (a thickness, a width, a length), a shape, a density, and the like. If these are different, a magnitude and a sign of the spin current affecting the first ferromagnetic layer 1 from each of the first region 25 and the second region 26 are different, and it can be said that the constituent elements are asymmetric from the viewpoint of the spin current.

The spin-orbit torque wiring 20 has different signs of the spin Hall angle depending on a material selected. Having different signs of the spin Hall angle means that when the same current is caused to flow through the spin-orbit torque wiring 20, polarization directions of the spins injected into the first ferromagnetic layer 1 are different, and magnetization directions of the first ferromagnetic layer 1 are in different states. Materials with a positive spin Hall angle include, for example, platinum (Pt), rhodium (Rh), palladium (Pd), tin (Sn), tantalum nitride (TiN), vanadium nitride (VN), chromium nitride (CrN), titanium oxynitride (TiON), vanadium oxynitride (VON), and chromium oxynitride (CrON). Materials with a negative spin Hall angle include, for example, tantalum (Ta), tungsten (W), niobium (Nb), molybdenum (Mo), tantalum Nitride (TaN), tungsten Nitride (WN), niobium nitride (NbN), molybdenum nitride (MoN), tantalum oxynitride (TaON), tungsten oxynitride (WON), niobium oxynitride (NbON), and molybdenum oxynitride (MoON).

The spin-orbit torque wiring 20 includes a first layer 21 and a second layer 22. The first layer 21 is closer to the first ferromagnetic layer 1 than the second layer 22 is. The first layer 21 and the second layer 22 are, for example, in direct contact with each other. An intermediate layer may be between the first layer 21 and the second layer 22.

The first layer 21 extends in the x direction. The first layer 21 extends over upper surfaces of the first insulating layer 91 sandwiching the laminate 10 and the laminate 10. The first layer 21 is, for example, plane-symmetric with respect to the reference plane RP. The reference plane RP is a plane that passes through a geometric center of the first ferromagnetic layer 1 when viewed from the z direction and is orthogonal to the x direction.

The first layer 21 has an overlapping part that overlaps the laminate 10 in the z direction and a non-overlapping part that does not overlap the laminate 10 in the z direction. A step may be between the overlapping part and the non-overlapping part.

The second layer 22 is, for example, in contact with a part of the first layer 21. The second layer 22 may be in direct contact with the first layer 21 or may be in contact therewith with a layer interposed. The second layer 22 overlaps, for example, a part of the laminate 10 in the z direction. The second layer 22 is, for example, asymmetric with respect to the reference plane RP. The spin-orbit torque wiring 20 as a whole is asymmetric in the x direction with respect to the reference plane RP.

In the magnetoresistance effect element 100 illustrated in FIG. 3, the first region 25 does not include the second layer 22 and is formed of the first layer 21. In the magnetoresistance effect element 100 illustrated in FIG. 3, the second region 26 includes the second layer 22 and is formed of the first layer 21 and the second layer 22. The first region 25 and the second region 26 have different layer configurations. The first region 25 and the second region 26 differ in the number of laminated layers. Further, the number of layers included in the first region 25 and the second region 26 is not limited to this example. As long as a condition that the constituent elements of the first region 25 and the second region 26 are different is satisfied, the number of layers in each region is not limited.

The first layer 21 and the second layer 22 are different in composition or crystal structure. Because of the difference in composition or crystal structure, a spin Hall angle of the first layer 21 and a spin Hall angle of the second layer 22 are different. The “spin Hall angle” is one of indicators of a strength of the spin Hall effect, and indicates a conversion efficiency of a spin current generated with respect to a current caused to flow along the wiring.

The first layer 21 and the second layer 22 may have different polarities of the spin Hall angle. For example, the first layer 21 may have a positive spin Hall angle and the second layer may have a negative spin Hall angle, or this relationship may be reversed. The polarity of the spin Hall angle changes according to a material forming the layer, a thickness of the layer, or the like.

If the polarities of the spin Hall angles are different, whether the spin current is generated from the first surface toward the second surface of the wiring or generated from the second surface toward the first surface of the wiring differs. When the polarities of the spin Hall angles are different, the polarities of the spins unevenly distributed on the first surface and the second surface are reversed. If the polarity of the spin Hall angle of the first layer 21 and the polarity of the spin Hall angle of the second layer 22 are different, a direction of the spins injected into the first ferromagnetic layer 1 from the first layer 21 is opposite to a direction of the spins injected into the first ferromagnetic layer 1 from the second layer 22.

The first layer 21 and the second layer 22 each contain a metal, an alloy, an intermetallic compound, a metal boride, a metal carbide, a metal silicide, a metal phosphide, or a metal nitride that has a function of generating a pure spin current due to the spin Hall effect when a current flows therethrough.

The first layer 21 contains, for example, a nonmagnetic heavy metal. The second layer 22 contains, for example, a nonmagnetic heavy metal. Here, the “heavy metal” means a metal having a specific gravity equal to or higher than that of yttrium.

The nonmagnetic heavy metal includes, for example, nonmagnetic metals having a high atomic number such as the atomic number of 39 or higher having d electrons or f electrons in the outermost shell. These nonmagnetic metals have a large spin-orbit interaction which causes the spin Hall effect.

Also, at least one of the first layer 21 and the second layer 22 may contain oxygen, nitrogen, or carbon. At least one of the first layer 21 and the second layer 22 may contain an oxide, a nitride, or a carbide. The first layer 21 and the second layer 22 may be an oxide, a nitride, or a carbide of a light metal.

The first layer 21 contains any one selected from the group consisting of, for example, platinum, rhodium, palladium, tin, titanium nitride, vanadium nitride, chromium nitride, titanium oxynitride, vanadium oxynitride, and chromium oxynitride. Particularly, tin with an a structure has a large spin Hall angle and has the same spin Hall angle as that of other topological materials.

The second layer 22 contains any one selected from the group consisting of, for example, tantalum, tungsten, niobium, molybdenum, tantalum nitride, tungsten nitride, niobium nitride, molybdenum nitride, tantalum oxynitride, tungsten oxynitride, niobium oxynitride, and molybdenum oxynitride.

A thickness of the first layer 21 is, for example, equal to or less than a spin diffusion length of a material forming the first layer 21. When this configuration is satisfied, spins generated in the second layer 22 can sufficiently reach the first ferromagnetic layer 1 through the first layer 21. Although a thickness of the second layer 22 is not particularly limited, it is, for example, 1 nm or more and 20 nm or less.

A resistivity of the spin-orbit torque wiring 20 is, for example, 1mΩ·cm or higher. Also, the resistivity of the spin-orbit torque wiring 20 is, for example, 10 mΩ·cm or lower. If the resistivity of the spin-orbit torque wiring 20 is high, a high voltage can be applied to the spin-orbit torque wiring 20. If a potential of the spin-orbit torque wiring 20 increases, spins can be efficiently supplied from the spin-orbit torque wiring 20 to the first ferromagnetic layer 1. Also, when the spin-orbit torque wiring 20 has a certain level or more of conductivity, a current path flowing along the spin-orbit torque wiring 20 can be secured, and a spin current associated with the spin Hall effect can be efficiently generated.

In addition to this, the spin-orbit torque wiring 20 may contain a magnetic metal or may contain a topological insulator. The topological insulator is a material in which the inside of the material is an insulator or a high resistance material, but a spin-polarized metallic state is generated on a surface thereof. For example, SnTe, Bi_{1.5}Sb_{0.5}Te_{1.7}Se_{1.3}, TlBiSe₂, Bi₂Te₃, Bi₁₋ₓSbₓ, (Bi₁₋ₓSbₓ)₂Te₃,and α-Sn are examples of the topological insulator. The topological insulator can generate spin currents with high efficiency.

The laminate 10 is connected to the spin-orbit torque wiring 20. The spin-orbit torque wiring 20 is laminated on the laminate 10. The laminate 10 and the spin-orbit torque wiring 20 may be in direct contact with each other, or may be in contact with each other with an intermediate layer interposed therebetween.

A resistance value of the laminate 10 in the z direction changes as spins are injected from the spin-orbit torque wiring 20 into the laminate 10 (the first ferromagnetic layer 1).

The laminate 10 is sandwiched between the spin-orbit torque wiring 20 and the electrode E (see FIG. 2) in the z direction. The laminate 10 is a columnar body. A shape of the laminate 10 in a plan view from the z direction is, for example, circular, elliptical, or quadrangular. A side surface of the laminate 10 is, for example, inclined with respect to the z direction.

The laminate 10 has, for example, the first ferromagnetic layer 1, the second ferromagnetic layer 2, and the nonmagnetic layer 3. The first ferromagnetic layer 1 is, for example, in contact with the spin-orbit torque wiring 20 and laminated on the spin-orbit torque wiring 20. Spins are injected into the first ferromagnetic layer 1 from the spin-orbit torque wiring 20. Magnetization of the first ferromagnetic layer 1 receives a spin-orbit torque (SOT) due to the injected spins and an orientation direction thereof is changed. The first ferromagnetic layer 1 and the second ferromagnetic layer 2 sandwich the nonmagnetic layer 3 in the z direction.

The first ferromagnetic layer 1 and the second ferromagnetic layer 2 each have magnetization. An orientation direction of a magnetization of the second ferromagnetic layer 2 is less likely to change than that of a magnetization of the first ferromagnetic layer 1 when a predetermined external force is applied. The first ferromagnetic layer 1 is referred to as a magnetization free layer, and the second ferromagnetic layer 2 is referred to as a magnetization fixed layer or a magnetization reference layer. The laminate 10 illustrated in FIG. 3 has the magnetization fixed layer closer to the substrate Sub with respect to the magnetization free layer, and this is called a bottom pin structure. A resistance value of the laminate 10 changes according to a difference in relative angle between the magnetization of the first ferromagnetic layer 1 and the magnetization of the second ferromagnetic layer 2 sandwiching the nonmagnetic layer 3.

The first ferromagnetic layer 1 and the second ferromagnetic layer 2 contain a ferromagnetic material. The ferromagnetic material is, for example, a metal selected from the group consisting of Cr, Mn, Co, Fe, and Ni, an alloy containing one or more of these metals, an alloy containing these metals and at least one element of B, C, and N, or the like. The ferromagnetic material is, for example, Co—Fe, Co—Fe—B, Ni—Fe, a Co—Ho alloy, a Sm—Fe alloy, an Fe—Pt alloy, a Co—Pt alloy, or a CoCrPt alloy.

The first ferromagnetic layer 1 and the second ferromagnetic layer 2 may contain a Heusler alloy. A Heusler alloy contains an intermetallic compound having a chemical composition of XYZ or X₂YZ. X indicates a transition metal element of the Co, Fe, Ni, or Cu group, or a noble metal element in the periodic table, Y indicates a transition metal of the Mn, V, Cr, or Ti group, or species of the X element, and Z indicates a typical element from Group III to Group V. The Heusler alloy is, for example, Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The nonmagnetic layer 3 contains a nonmagnetic material. When the nonmagnetic layer 3 is an insulator (in a case of a tunnel barrier layer), for example, Al₂O₃, SiO₂, MgO, MgAl₂O₄, or the like can be used for a material thereof. Also, in addition to these materials, a material in which a part of Al, Si, and Mg is substituted with Zn, Be, or the like can also be used. Of these, since MgO and MgAl₂0₄ are materials that can realize coherent tunneling, spins can be efficiently injected. If the nonmagnetic layer 3 is a metal, Cu, Au, Ag, or the like can be used for a material thereof. Further, if the nonmagnetic layer 3 is a semiconductor, Si, Ge, CuInSe₂, CuGaSe₂, Cu(In, Ga)Se₂, or the like can be used for a material thereof.

The laminate 10 may have a layer other than the first ferromagnetic layer 1, the second ferromagnetic layer 2, and the nonmagnetic layer 3. For example, an underlayer may be provided between the spin-orbit torque wiring 20 and the first ferromagnetic layer 1. The underlayer enhances crystallinity of each layer constituting the laminate 10.

Also, the laminate 10 may have a ferromagnetic layer provided on a surface of the second ferromagnetic layer 2 opposite to the nonmagnetic layer 3 via a spacer layer. The second ferromagnetic layer 2, the spacer layer, and the ferromagnetic layer have a synthetic antiferromagnetic structure (SAF structure). The synthetic antiferromagnetic structure is made of two magnetic layers sandwiching a nonmagnetic layer therebetween. When the second ferromagnetic layer 2 and the ferromagnetic layer are antiferromagnetically coupled, a coercive force of the second ferromagnetic layer 2 is larger than that in a case without the ferromagnetic layer. The ferromagnetic layer is, for example, IrMn, PtMn, or the like. The spacer layer contains, for example, at least one selected from the group consisting of Ru, Ir, and Rh.

The cap layer 30 is, for example, between the laminate 10 and the spin-orbit torque wiring 20. The cap layer 30 may be omitted. The cap layer 30 may be a part of a mask when the laminate 10 is manufactured. Cap layer 30 is any one of, for example, tungsten, tantalum, ruthenium, titanium, silicon, copper, tantalum nitride, titanium nitride, tungsten nitride, niobium nitride, or vanadium nitride. The cap layer 30 enhances magnetic anisotropy of the first ferromagnetic layer 1. A thickness of the cap layer 30 is, for example, equal to or less than a spin diffusion length of the cap layer 30.

Next, a manufacturing method of the magnetoresistance effect element 100 will be described. The magnetoresistance effect element 100 is formed by a laminating step of each layer, and a processing step of processing a part of each layer into a predetermined shape. A sputtering method, a chemical vapor deposition (CVD) method, an electron beam evaporation method (EB evaporation method), an atomic laser deposition method, an ion beam deposition (IBD) method, or the like can be used for lamination of each layer. Processing of each layer can be performed using photolithography, or the like.

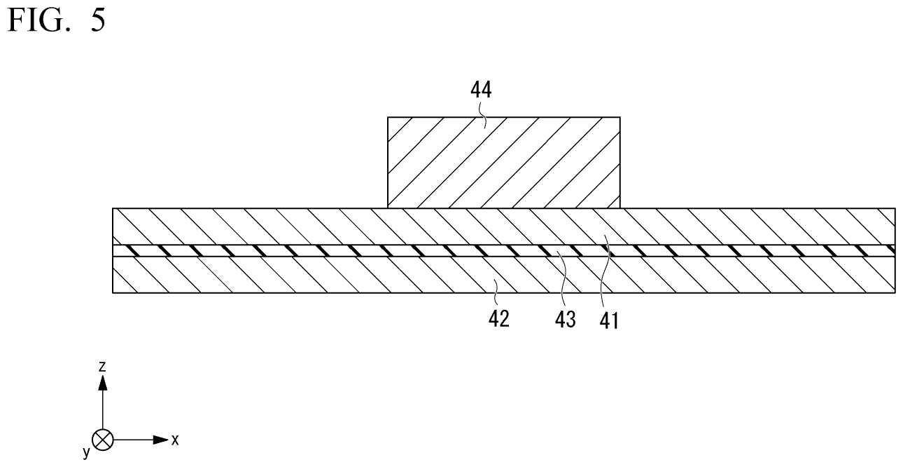

First, as illustrated in FIG. 5, a ferromagnetic layer 42, a nonmagnetic layer 43, and a ferromagnetic layer 41 are laminated in order. The ferromagnetic layer 42 is laminated on, for example, the substrate Sb or the insulating layer In. Then, a mask 44 is formed at a predetermined position of the ferromagnetic layer 41.

Next, the laminate is subjected to anisotropic etching through the mask 44. Due to the etching, a lower part of the mask remains, the ferromagnetic layer 42 becomes the second ferromagnetic layer 2, the nonmagnetic layer 43 becomes the nonmagnetic layer 3, and the ferromagnetic layer 41 becomes the first ferromagnetic layer 1.

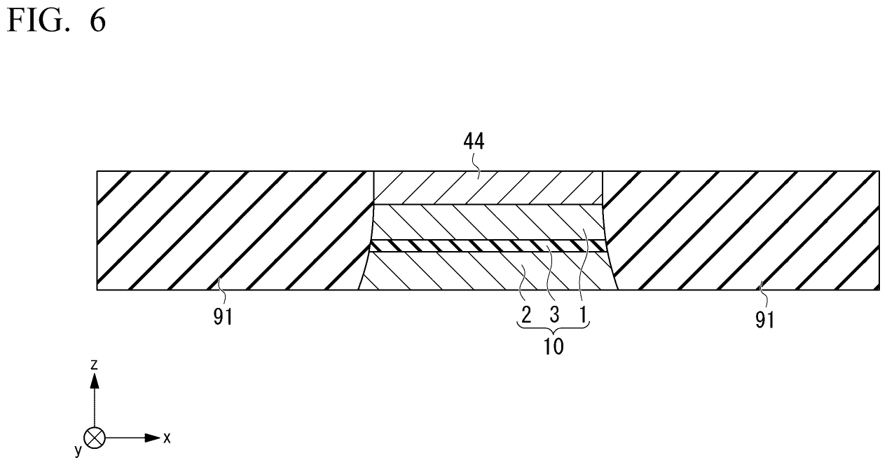

Next, the first insulating layer 91 is formed to cover the laminate 10. Then, as illustrated in FIG. 6, one surface of the first insulating layer 91 is removed to expose one surface of the mask 44. Removal of the first insulating layer 91 is performed by, for example, chemical mechanical polishing (CMP).

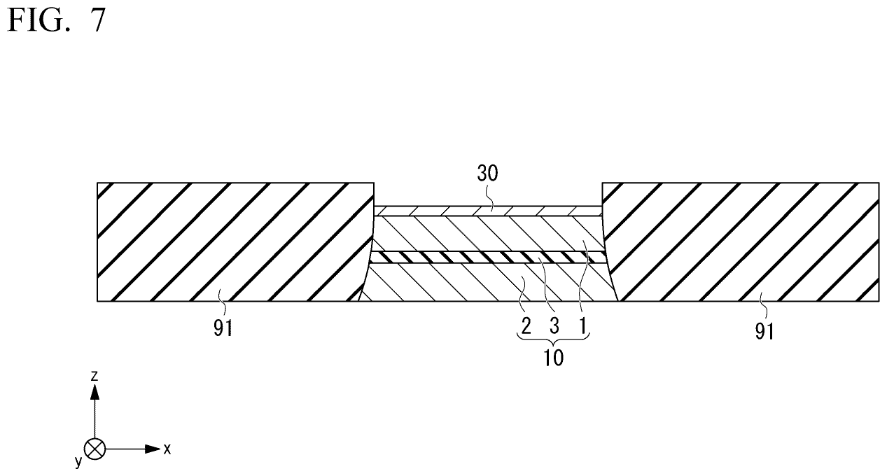

Next, one surface of the mask 44 and first insulating layer 91 is subjected to reactive ion etching (RIE). As illustrated in FIG. 7, a part of the mask 44 is removed by RIE to form the cap layer 30. All of the mask 44 may be removed by RIE. Since the mask 44 and the first insulating layer 91 have different hardness, for example, the surface of the cap layer 30 is positioned below the surface of the first insulating layer 91.

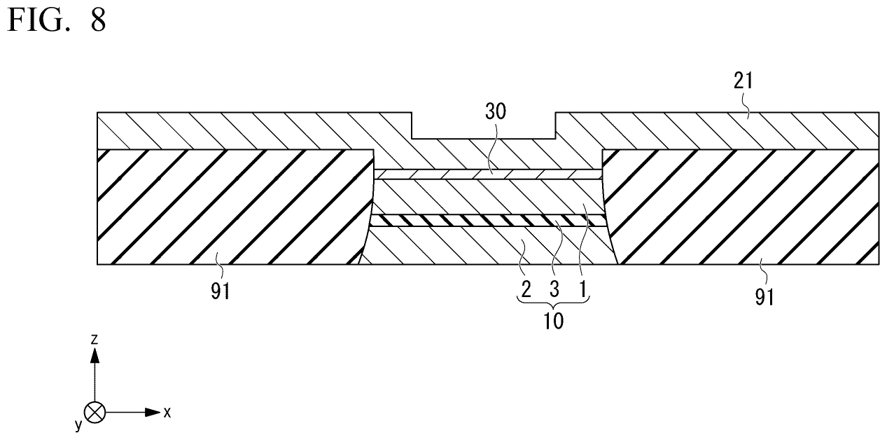

Next, as illustrated in FIG. 8, the first layer 21 is formed on the first insulating layer 91 and the cap layer 30.

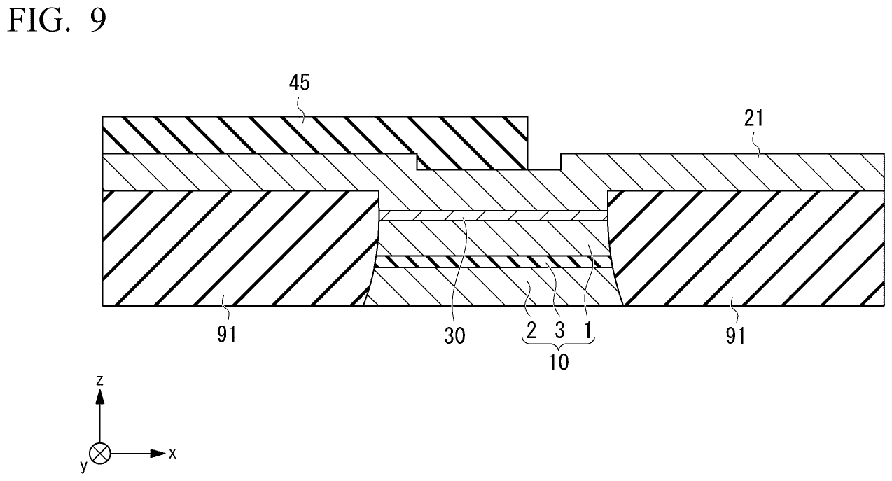

Next, as illustrated in FIG. 9, a protective layer 45 is formed to partially cover an upper surface of the first layer 21. The protective layer 45 is, for example, silicon oxide, silicon nitride, silicon oxynitride, or resist.

Next, the second layer 22 is formed with the protective layer 45 interposed. As a result, the second layer 22 is formed on a portion of the first layer 21 not covered with the protective layer 45. With such a procedure, the magnetoresistance effect element 100 according to the first embodiment can be manufactured.

The magnetoresistance effect element 100 according to the first embodiment has the first region 25 and the second region 26 at positions symmetrical in the x direction with respect to the reference plane RP, in which the first region 25 and the second region 26 have different constituent elements. Therefore, an amount of spin injected into the first ferromagnetic layer 1 from the first region 25 is different from an amount of spin injected into the first ferromagnetic layer 1 from the second region 26. For example, in the magnetoresistance effect element 100 illustrated in FIG. 3, only spins generated in the first layer 21 are injected from the first region 25 into the spin-orbit torque wiring 20.

On the other hand, in the magnetoresistance effect element 100 illustrated in FIG. 3, superimposed spins of spins generated in the first layer 21 and spins generated in the second layer 22 are injected from the second region 26 into the spin-orbit torque wiring 20.

A torque applied to the magnetization of the first ferromagnetic layer 1 varies depending on a position of the first ferromagnetic layer 1 in the x direction. That is, an inversion symmetry of the magnetization of the first ferromagnetic layer 1 is broken in the x direction. In the magnetoresistance effect element 100 according to the first embodiment, the inversion symmetry of the magnetization of the first ferromagnetic layer 1 is broken even without applying an external magnetic field. Therefore, the magnetoresistance effect element 100 according to the first embodiment can stably reverse magnetization of the first ferromagnetic layer 1 even in an absence of a magnetic field.

### Second Embodiment

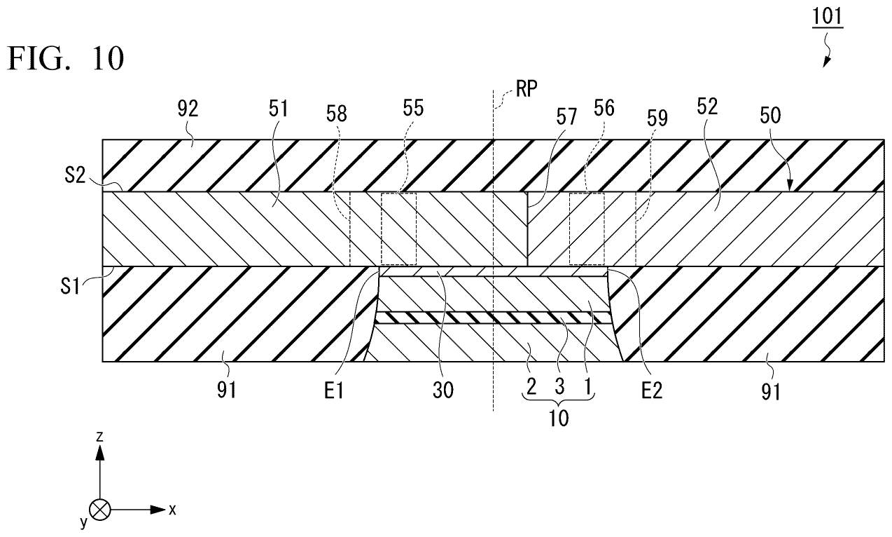

FIG. 10 is a cross-sectional view of a magnetoresistance effect element 101 according to a second embodiment. FIG. 10 is a cross section of the magnetoresistance effect element 101 taken along an xz plane passing through a center of a width of a spin-orbit torque wiring 50 in the y direction. A plan view of the magnetoresistance effect element 101 is the same as that of FIG. 4. In the magnetoresistance effect element 101, components the same as those in the magnetoresistance effect element 100 will be denoted by the same reference signs, and description thereof will be omitted.

The magnetoresistance effect element 101 includes, for example, a laminate 10, the spin-orbit torque wiring 50, and a cap layer 30. The magnetoresistance effect element 101 differs from the magnetoresistance effect element 100 in configuration of the spin-orbit torque wiring 50. The magnetoresistance effect element 101 can be interchangeable with the magnetoresistance effect element 100.

The spin-orbit torque wiring 50 differs from the spin-orbit torque wiring 20 in layer configuration. A function of the spin-orbit torque wiring 50 is similar to that of the spin-orbit torque wiring 20.

The spin-orbit torque wiring 50 has a first region 55 and a second region 56.

Both the first region 55 and the second region 56 are regions surrounding a predetermined range in the spin-orbit torque wiring 50.

The first region 55 and the second region 56 are at positions symmetrical in the x direction with respect to a reference plane RP. The first region 55 and the second region 56 have different constituent elements. The first region 55 is formed of the first layer 51, and the second region 56 is formed of the second layer 52.

The spin-orbit torque wiring 50 includes the first layer 51 and the second layer 52. The first layer 51 and the second layer 52 are at different positions in the x direction. For example, lateral surfaces of the first layer 51 and the second layer 52 are in direct contact with each other. An intermediate layer may be between the first layer 51 and the second layer 52.

The first layer 51 and the second layer 52 are different in, for example, a composition, a crystal structure, a layer configuration, or a constituent material. The spin-orbit torque wiring 50 as a whole is asymmetric in the x direction with respect to the reference plane RP. A material similar to that of the first layer 21 can be used for the first layer 51. A material similar to that of the second layer 22 can be used for the second layer 52.

A boundary surface 57 is provided between the first layer 51 and the second layer 52. On a first surface S1 of the spin-orbit torque wiring 50 on a side closer to a first ferromagnetic layer 1, the boundary surface 57 is positioned at a position between a first surface 58 and a second surface 59. The first surface 58 is at a position away from the reference plane RP toward an outer side by a spin diffusion length of the second layer 52 from a first end E1 of the first ferromagnetic layer 1 in the x direction. The second surface 59 is at a position away from the reference surface RP toward an outer side by a spin diffusion length of the first layer 51 from a second end E2 of the first ferromagnetic layer 1 in the x direction. If the boundary surface 57 is within this range, spins generated in each of the first layer 51 and the second layer 52 can be sufficiently injected into the first ferromagnetic layer 1.

The magnetoresistance effect element 101 according to the second embodiment can be manufactured by the same procedure as the magnetoresistance effect element 100 according to the first embodiment up to the procedure illustrated in FIG. 6 or FIG. 7. The spin-orbit torque wiring 50 can be manufactured by, for example, forming the first layer 51 and the second layer 52 only at predetermined positions using a mask. The spin-orbit torque wiring 50 may also be manufactured by removing unnecessary portions after depositing the first layer 51 and then forming the second layer 52 at the removed portions.

The magnetoresistance effect element 101 according to the second embodiment has the first region 55 and the second region 56 at positions symmetrical in the x direction with respect to the reference plane RP, in which the first region 55 and the second region 56 have different constituent elements. Therefore, an inversion symmetry of magnetization of the first ferromagnetic layer 1 is broken in the x direction. Therefore, the magnetoresistance effect element 101 according to the second embodiment can stably reverse magnetization of the first ferromagnetic layer 1 even in an absence of a magnetic field.

### Third Embodiment

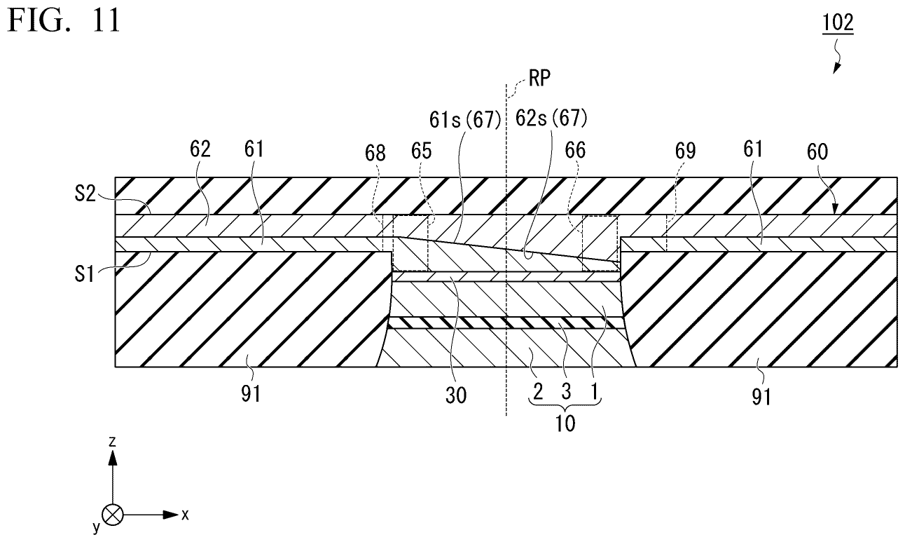

FIG. 11 is a cross-sectional view of a magnetoresistance effect element 102 according to a third embodiment. FIG. 11 is a cross section of the magnetoresistance effect element 102 taken along an xz plane passing through a center of a width of a spin-orbit torque wiring 60 in the y direction. A plan view of the magnetoresistance effect element 102 is the same as that of FIG. 4. In the magnetoresistance effect element 102, components the same as those in the magnetoresistance effect element 100 will be denoted by the same reference signs, and description thereof will be omitted.

The magnetoresistance effect element 102 includes, for example, a laminate 10, the spin-orbit torque wiring 60, and a cap layer 30. The magnetoresistance effect element 102 differs from the magnetoresistance effect element 100 in configuration of the spin-orbit torque wiring 60. The magnetoresistance effect element 102 can be interchangeable with the magnetoresistance effect element 100.

The spin-orbit torque wiring 60 differs from the spin-orbit torque wiring 20 in layer configuration. A function of the spin-orbit torque wiring 60 is similar to that of the spin-orbit torque wiring 20.

The spin-orbit torque wiring 60 has a first region 65 and a second region 66. Both the first region 65 and the second region 66 are regions surrounding a predetermined range in the spin-orbit torque wiring 50.

The first region 65 and the second region 66 are at positions symmetrical in the x direction with respect to a reference plane RP. The first region 65 and the second region 66 have different constituent elements. Both the first region 65 and the second region 66 are formed of a first layer 61 and a second layer 62. A proportion of the first layer 61 occupying the first region 65 differs from a proportion of the first layer 61 occupying the second region 66.

The spin-orbit torque wiring 60 includes the first layer 61 and the second layer 62. The second layer 62 is, for example, on the first layer 61. For example, lateral surfaces of the first layer 61 and the second layer 62 are in direct contact with each other. An intermediate layer may be between the first layer 61 and the second layer 62.

The first layer 61 and the second layer 62 are different in, for example, a composition, a crystal structure, a layer configuration, or a constituent material. The spin-orbit torque wiring 60 as a whole is asymmetric in the x direction with respect to the reference plane RP. A material similar to that of the first layer 21 can be used for the first layer 61. A material similar to that of the second layer 22 can be used for the second layer 62.

A boundary surface 67 is provided between the first layer 61 and the second layer 62. The boundary surface 67 is preferably between a first surface 68 and a second surface 69. The first surface 68 corresponds to the first surface 58, and the second surface 69 corresponds to the second surface 59. The boundary surface 67 on a first surface S1 is more preferably at a position overlapping the first ferromagnetic layer 1 in the z direction.

The boundary surface 67 is inclined, for example, in the x direction with respect to the z direction. A first boundary surface 61s of the first layer 61 facing the second layer 62 in the x direction is inclined in the x direction with respect to the z direction. A second boundary surface 62s of the second layer 62 facing the first layer 61 in the x direction is inclined in the x direction with respect to the z direction.

The magnetoresistance effect element 102 according to the third embodiment can be manufactured by the same procedure as the magnetoresistance effect element 100 according to the first embodiment up to the procedure illustrated in FIG. 7.

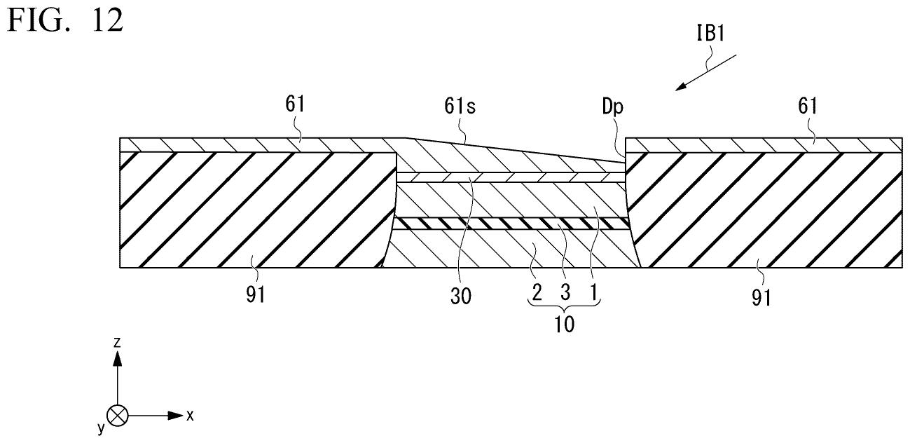

The spin-orbit torque wiring 60 can be manufactured by the following procedure. First, the first layer 61 is formed on a first insulating layer 91 and the cap layer 30 using an ion beam deposition (IBD) method. As illustrated in FIG. 12, an ion beam IB1 at the time of depositing the first layer 61 is applied from a direction inclined from the z direction to the +x direction. When the ion beam IB1 is applied from an oblique direction, one side (front side in a beam irradiation direction) in a recessed part Dp is in a shadow of the first insulating layer 91 forming a side wall of the recessed part Dp, and this makes it difficult to form a layer due to a shadowing effect. As a result, the first boundary surface 61s of the first layer 61 is inclined in the x direction.

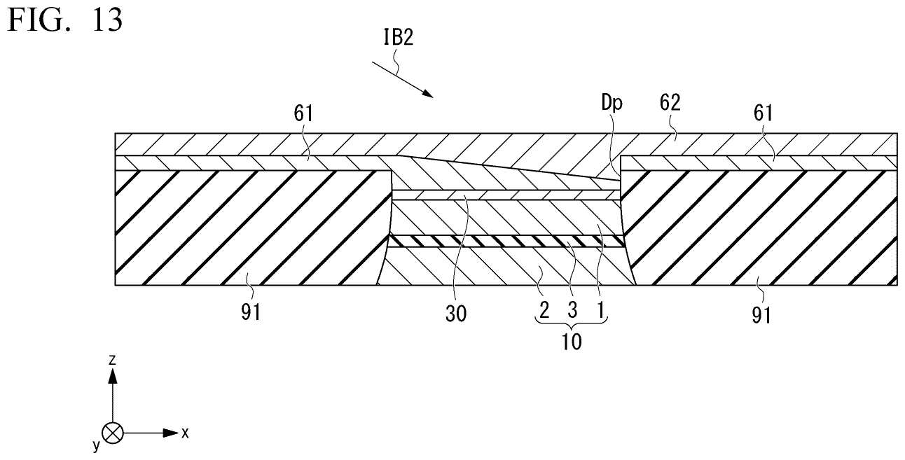

Next, the second layer 62 is formed on the first layer 61 using an ion beam deposition (IBD) method. As illustrated in FIG. 13, an ion beam IB2 at the time of depositing the second layer 62 is applied from a direction inclined from the z direction to the —x direction. An irradiation direction of the ion beam IB2 is opposite to the irradiation direction of the ion beam IB1 in the x direction.

Due to the irradiation with the ion beam IB2, the second layer 62 is formed only in the film deposition portion of the recessed part Dp, and thereby the spin-orbit torque wiring 60 is obtained.

The magnetoresistance effect element 102 according to the third embodiment has the first region 65 and the second region 66 at positions symmetrical in the x direction with respect to the reference plane RP, in which the first region 65 and the second region 66 have different constituent elements. Therefore, an inversion symmetry of magnetization of the first ferromagnetic layer 1 is broken in the x direction. Therefore, the magnetoresistance effect element 102 according to the third embodiment can stably reverse magnetization of the first ferromagnetic layer 1 even in an absence of a magnetic field.

### Fourth Embodiment

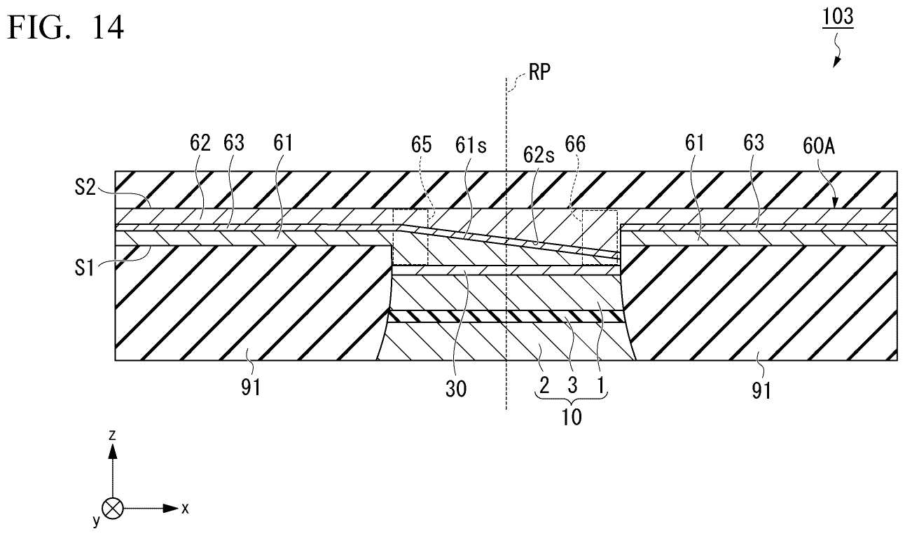

FIG. 14 is a cross-sectional view of a magnetoresistance effect element 103 according to a fourth embodiment. FIG. 14 is a cross section of the magnetoresistance effect element 103 taken along an xz plane passing through a center of a width of a spin-orbit torque wiring 60A in the y direction. A plan view of the magnetoresistance effect element 103 is the same as that of FIG. 4. In the magnetoresistance effect element 103, components the same as those in the magnetoresistance effect element 102 will be denoted by the same reference signs, and description thereof will be omitted.

The magnetoresistance effect element 103 differs from the magnetoresistance effect element 102 in configuration of the spin-orbit torque wiring 60A. The spin-orbit torque wiring 60A differs from the spin-orbit torque wiring 60 in that it has an intermediate layer 63. The magnetoresistance effect element 103 can be interchangeable with the magnetoresistance effect element 100.

The intermediate layer 63 is between a first layer 61 and a second layer 62. The intermediate layer 63 contains any one of ruthenium, iridium, copper, aluminum, silver, and silicon. The intermediate layer 63 suppresses interference of spins between the first layer 61 and the second layer 62. A thickness of the intermediate layer 63 is preferably equal to or less than a spin diffusion length of the intermediate layer 63. The spin-orbit torque wiring 60A having the intermediate layer 63 has a large number of lamination interfaces and can allow more efficient injection into a first ferromagnetic layer 1 due to the Rashba effect.

The magnetoresistance effect element 103 according to the fourth embodiment can be manufactured by the same procedure as the magnetoresistance effect element 102 according to the third embodiment as long as the intermediate layer 63 is deposited before the second layer 62 is formed.

The magnetoresistance effect element 103 according to the fourth embodiment has a first region 65 and a second region 66 at positions symmetrical in the x direction with respect to the reference plane RP, in which the first region 65 and the second region 66 have different constituent elements. Therefore, an inversion symmetry of magnetization of the first ferromagnetic layer 1 is broken in the x direction. Therefore, the magnetoresistance effect element 103 according to the fourth embodiment can stably reverse magnetization of the first ferromagnetic layer 1 even in an absence of a magnetic field.

### Fifth Embodiment

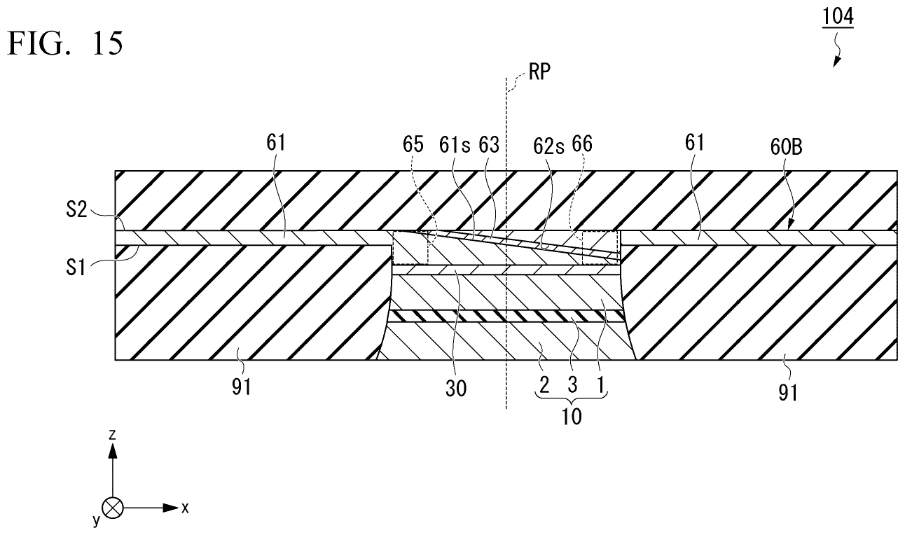

FIG. 15 is a cross-sectional view of a magnetoresistance effect element 104 according to a fifth embodiment. FIG. 15 is a cross section of the magnetoresistance effect element 104 taken along an xz plane passing through a center of a width of a spin-orbit torque wiring 60B in the y direction. A plan view of the magnetoresistance effect element 104 is the same as that of FIG. 4. In the magnetoresistance effect element 104, components the same as those in the magnetoresistance effect element 103 will be denoted by the same reference signs, and description thereof will be omitted.

The magnetoresistance effect element 104 differs from the magnetoresistance effect element 103 in configuration of the spin-orbit torque wiring 60B. The magnetoresistance effect element 104 can be interchangeable with the magnetoresistance effect element 100. The spin-orbit torque wiring 60B is obtained by removing an upper portion of the spin-orbit torque wiring 60A. A first layer 61, a second layer 62, and an intermediate layer 63 are exposed on a second surface S2 of the spin-orbit torque wiring 60B on a side far from the first ferromagnetic layer 1.

The magnetoresistance effect element 104 according to the fifth embodiment can obtain the same effects as those of the magnetoresistance effect element 103 according to the fourth embodiment. Also, since a thickness of the spin-orbit torque wiring 60B is small, a current density of the spin-orbit torque wiring 60B can be increased.

### Sixth Embodiment

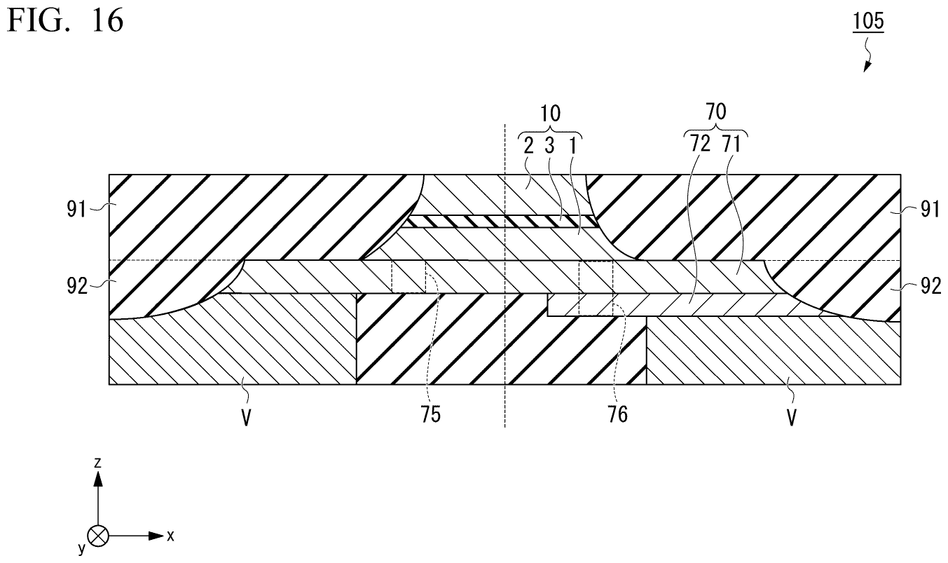

FIG. 16 is a cross-sectional view of a magnetoresistance effect element 105 according to a sixth embodiment. FIG. 16 is a cross section of the magnetoresistance effect element 105 taken along an xz plane passing through a center of a width of a spin-orbit torque wiring 70 in the y direction. A plan view of the magnetoresistance effect element 105 is the same as that of FIG. 4. In the magnetoresistance effect element 105, components the same as those in the magnetoresistance effect element 100 will be denoted by the same reference signs, and description thereof will be omitted.

The magnetoresistance effect element 105 includes, for example, a laminate 10 and the spin-orbit torque wiring 70. The magnetoresistance effect element 105 differs from the magnetoresistance effect element 100 in a lamination order of the laminate 10 and the spin-orbit torque wiring 70. The magnetoresistance effect element 105 can be interchangeable with the magnetoresistance effect element 100.

The spin-orbit torque wiring 70 has a first layer 71 and a second layer 72. The first layer 71 is similar to the first layer 21, and the second layer 72 is similar to the second layer 22. The first layer 71 is on the second layer 72. The second layer 72 is partially in contact with the first layer 71. The spin-orbit torque wiring 70 has a first region 75 and a second region 76. The first region 75 and the second region 76 are at positions symmetrical in the x direction with respect to a reference plane RP. The first region 75 and the second region 76 have different constituent elements.

The laminate 10 illustrated in FIG. 16 has a top-pin structure in which a magnetization fixed layer (second ferromagnetic layer 2) is at a position further away from a substrate Sub with respect to a magnetization free layer (first ferromagnetic layer 1).

The magnetoresistance effect element 105 according to the sixth embodiment differs only in a positional relationship of each component, and can obtain the same effects as those of the magnetoresistance effect element 100 according to the first embodiment. Also, a case in which the magnetoresistance effect element 100 according to the first embodiment has the top-pin structure has been illustrated here, but the magnetoresistance effect elements according to the second to fifth embodiments may be configured to have the top-pin structure.

### Seventh Embodiment

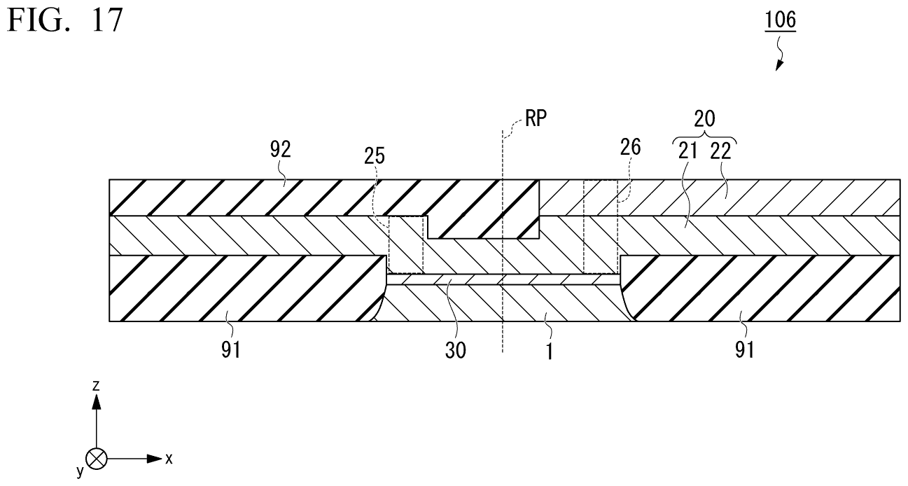

FIG. 17 is a cross-sectional view of a magnetization rotational element 106 according to a seventh embodiment. In FIG. 17, the magnetization rotational element 106 can be replaced with the magnetoresistance effect element 100 according to the first embodiment.

The magnetization rotational element 106, for example, causes light to be incident on a first ferromagnetic layer 1 and evaluates the light reflected by the first ferromagnetic layer 1. When an orientation direction of magnetization changes due to a magnetic Kerr effect, a polarization state of the reflected light changes. The magnetization rotational element 106 can be used as, for example, an optical element such as a video display device utilizing, for example, a difference in polarization state of light.

In addition, the magnetization rotational element 106 can be used singly as an anisotropic magnetic sensor, an optical element utilizing a magnetic Faraday effect, or the like.

A spin-orbit torque wiring 20 of the magnetization rotational element 106 has a first layer 21 and a second layer 22.

The magnetization rotational element 106 according to the seventh embodiment is one in which only the nonmagnetic layer 3 and the second ferromagnetic layer 2 are removed from the magnetoresistance effect element 100, and can obtain the same effects as those of the magnetoresistance effect element 100 according to the first embodiment. Also, the nonmagnetic layer 3 and the second ferromagnetic layer 2 may be removed from each of the second to sixth embodiments to form a magnetization rotational element.

As described above, preferred aspects of the present invention have been exemplified on the basis of several embodiments, but the present invention is not limited to these embodiments. For example, characteristic configurations in each of the embodiments and modified examples may be applied to other embodiments.

### REFERENCE SIGNS LIST

1 First ferromagnetic layer
2 Second ferromagnetic layer
3 Nonmagnetic layer
10 Laminate
20, 50, 60, 60A, 60B, 70 Spin-orbit torque wiring
21, 51, 61, 71 First layer
22, 52, 62, 72 Second layer
25, 55, 65, 75 First region
26, 56, 66, 76 Second region
30 Cab layer
57, 67 boundary surface
61s First boundary surface
62s Second boundary surface
63 Intermediate layer
100, 101, 102, 103, 104, 105 Magnetoresistance effect element
106 Magnetization rotational element
200 Magnetic memory
E1 First end
E2 Second end
RP Reference plane

1. A magnetization rotational element comprising:
a spin-orbit torque wiring; and
a first ferromagnetic layer connected to the spin-orbit torque wiring, wherein
the spin-orbit torque wiring has a length in a first direction larger than a length in a second direction when viewed from a lamination direction, and
the spin-orbit torque wiring has different constituent elements between a first region and a second region having a symmetrical positional relationship with respect to a reference plane which passes through a geometric center of the first ferromagnetic layer when viewed from the lamination direction and is orthogonal to the first direction, and is asymmetrical in the first direction.

2. The magnetization rotational element according to claim 1, wherein
the spin-orbit torque wiring includes a first layer and a second layer,
the second layer is in contact with a part of the first layer,
the first region does not include the second layer, and
the second region includes the second layer.

3. The magnetization rotational element according to claim 1, wherein
the spin-orbit torque wiring includes a first layer and a second layer,
the first layer and the second layer are at different positions in the first direction,
the first region is formed of the first layer, and
the second region is formed of the second layer.

4. The magnetization rotational element according to claim 1, wherein
the spin-orbit torque wiring includes a first layer and a second layer,
the second layer is in contact with the second layer, and
a proportion of the first layer occupying the first region is different from a proportion of the first layer occupying the second region.

5. The magnetization rotational element according to claim 3, wherein a first boundary surface of the first layer facing the second layer in the first direction is inclined with respect to the lamination direction.

6. The magnetization rotational element according to claim 5, wherein a second boundary surface of the second layer facing the first layer in the first direction is inclined with respect to the lamination direction.

7. The magnetization rotational element according to claim 3, wherein a boundary between the first layer and the second layer on a first surface of the spin-orbit torque wiring on a side closer to the first ferromagnetic layer is between a position outward of the reference plane by a spin diffusion length of the second layer from a first end of the first ferromagnetic layer in the first direction and a position outward of the reference plane by a spin diffusion length of the first layer from a second end opposite to the first end in the first direction.

8. The magnetization rotational element according to any claim 2, wherein the first layer and the second layer have different polarities of a spin Hall angle.

9. The magnetization rotational element according to any claim 2, wherein the first layer contains any one selected from the group consisting of platinum, rhodium, palladium, tin, titanium nitride, vanadium nitride, chromium nitride, titanium oxynitride, vanadium oxynitride, and chromium oxynitride.

10. The magnetization rotational element according to claim 2, wherein the second layer contains any one selected from the group consisting of tantalum, tungsten, niobium, molybdenum, tantalum nitride, tungsten nitride, niobium nitride, molybdenum nitride, tantalum oxynitride, tungsten oxynitride, niobium oxynitride, and molybdenum oxynitride.

11. The magnetization rotational element according to claim 4, further comprising an intermediate layer between the first layer and the second layer.

12. The magnetization rotational element according to claim 11, wherein the intermediate layer contains any one of ruthenium, iridium, copper, aluminum, silver, and silicon.

13. The magnetization rotational element according to claim 11, wherein the first layer, the second layer, and the intermediate layer are exposed on a second surface of the spin-orbit torque wiring on a side far from the first ferromagnetic layer.

14. A magnetoresistance effect element comprising the magnetization rotational element according to claim 1, a nonmagnetic layer, and a second ferromagnetic layer, wherein
the nonmagnetic layer is sandwiched between the first ferromagnetic layer and the second ferromagnetic layer, and
the first ferromagnetic layer is closer to the spin-orbit torque wiring than the second ferromagnetic layer is.

15. A magnetic memory comprising a plurality of magnetoresistance effect elements according to claim 14.

16. The magnetization rotational element according to claim 4, wherein a first boundary surface of the first layer facing the second layer in the first direction is inclined with respect to the lamination direction.

17. The magnetization rotational element according to claim 4, wherein a boundary between the first layer and the second layer on a first surface of the spin-orbit torque wiring on a side closer to the first ferromagnetic layer is between a position outward of the reference plane by a spin diffusion length of the second layer from a first end of the first ferromagnetic layer in the first direction and a position outward of the reference plane by a spin diffusion length of the first layer from a second end opposite to the first end in the first direction.

18. The magnetization rotational element according to claim 3, wherein the first layer contains any one selected from the group consisting of platinum, rhodium, palladium, tin, titanium nitride, vanadium nitride, chromium nitride, titanium oxynitride, vanadium oxynitride, and chromium oxynitride.

19. The magnetization rotational element according to claim 4, wherein the first layer contains any one selected from the group consisting of platinum, rhodium, palladium, tin, titanium nitride, vanadium nitride, chromium nitride, titanium oxynitride, vanadium oxynitride, and chromium oxynitride.
